(19) United States
(12) Patent Application Publication
(10) Pub. No.: US 2024/0019502 A1
(43) Pub. Date: Jan. 18, 2024

(54) OVERLOAD CAPABILITY AND REMAINING LIFE OF AN ELECTRICAL ASSET

(71) Applicant: Eaton Intelligent Power Limited, Dublin (IE)

(72) Inventors: Bubathi Muruganantham, Pune (IN); Prasad Arvind Venikar, Pune (IN); Balachandar D, Madurai (IN); Mugdha Vyankatesh Limaye, Pune (IN); Mark Andre Faulkner, Greenwood, SC (US); Travis Vernon Spoone, Greenwood, SC (US); Robert Edward Page, Indianapolis, IN (US); Antonio Romero Oruga, Greenwood, SC (US); Swetha Prakash, Palakkad (IN)

(21) Appl. No.: 18/216,667

(22) Filed: Jun. 30, 2023

Related U.S. Application Data
(60) Provisional application No. 63/358,629, filed on Jul. 6, 2022.

(51) Int. Cl. G01R 31/62

(52) U.S. Cl. CPC G01R 31/62

(57) ABSTRACT

A system includes: an electrical apparatus that includes: a housing that defines an interior space; an active portion in the interior space; and insulation configured to electrically insulate at least part of the active portion. The system also includes a monitoring apparatus configured to: receive measured data from the electrical apparatus; determine a load forecast for the electrical apparatus based on the measured data; determine whether a pre-determined time interval has elapsed; and after the pre-determined time interval has elapsed: estimate an actual amount of life lost for the insulation during the pre-determined time interval that elapsed based on the measured data; estimate a predicted amount of life lost for the insulation during one or more future time intervals based on the load forecast; and estimate a remaining service life for the electrical apparatus based on the actual amount of life lost and the predicted amount of life lost.

### CROSS-REFERENCE TO RELATED APPLICATION

This application claims the benefit of U.S. Provisional Application No. 63/358,629, filed on Jul. 6, 2022 and titled OVERLOAD CAPABILITY AND REMAINING LIFE OF AN ELECTRICAL ASSET, which is incorporated herein by reference in its entirety.

### TECHNICAL FIELD

This disclosure relates to determining or estimating an overload capability and a remaining life of an electrical asset. The electrical asset may be, for example, a transformer.

### BACKGROUND

An electrical asset, such as transformer, may be used as part of an electrical system that distributes time-varying or alternating current (AC) electrical power. The electrical system may include other electrical assets, such as, for example, voltage regulators, inductors, transmission lines, and switches.

### SUMMARY

In one aspect, a system includes: an electrical apparatus that includes: a housing that defines an interior space; an active portion in the interior space; and insulation configured to electrically insulate at least part of the active portion. The system also includes a monitoring apparatus configured to: receive measured data from the electrical apparatus; determine a load forecast for the electrical apparatus based on the measured data; determine whether a pre-determined time interval has elapsed; and after the pre-determined time interval has elapsed: estimate an actual amount of life lost for the insulation during the pre-determined time interval that elapsed based on the measured data; estimate a predicted amount of life lost for the insulation during one or more future time intervals based on the load forecast; and estimate a remaining service life for the electrical apparatus based on the actual amount of life lost and the predicted amount of life lost.

Implementations include one or more of the following features.

The monitoring apparatus may be further configured to: compare the estimated remaining service life to an expected lifetime of the electrical apparatus; and, if the estimated remaining service life is greater than or equal to the expected lifetime, the monitoring apparatus may be configured to: determine whether a subsequent pre-determined time interval has elapsed; receive additional measured data from the electrical apparatus; and, after the subsequent pre-determined time interval has elapsed, estimate the actual amount of life lost for the insulation during the subsequent pre-determined time interval based on the additional measured data.

The monitoring apparatus may be further configured to estimate an initial amount of life lost for the insulation, where the initial amount of life lost is the amount of life lost between an initial use of the electrical asset and an assessment time; and the remaining service life for the electrical apparatus may be estimated based on the actual amount of life lost, the predicted amount of life lost, and the initial amount of life lost. The assessment time may occur when a command requesting a service life estimate is received at the monitoring apparatus. The assessment time may be a pre-defined time period measured from the initial use of the electrical asset. The initial amount of life lost may be based on measured data associated with times between the initial use of the electrical asset and the assessment time, and an aging factor.

The active portion may include one or more electrically conductive coils, and the insulation is configured to electrically insulate the coils. The electrical apparatus may be a transformer.

The measured data may include measurements related to electrical current that flows in the one or more coils.

The measurements may include numerical values that represent any of current, voltage, and power.

In another aspect, a system includes: an electrical apparatus that includes: a housing that defines an interior space; an active portion in the interior space; and insulation configured to electrically insulate at least part of the active portion. The system also includes a monitoring apparatus configured to: access one or more desired load parameters related to future operation of the electrical asset; predict a hotspot temperature of the insulation based on each of the one or more desired load parameters; and estimate an overload capability of the electrical asset based on the predicted hotspot temperature. The overload capability includes at least one desired load factor and a time duration during which the electrical asset is capable of being operated at the determined load factor.

Implementations may include one or more of the following features.

The monitoring apparatus also may be configured to determine an initial hotspot temperature prior to predicting the hotspot temperature of the insulation based on each of the desired load parameters.

The one or more desired load parameters may include one or more desired load factors, and each desired load factor may represent a ratio between a requested load of the electrical asset and a rated load of the electrical asset. At least one of the desired load factors may be greater than 1.

The electrical asset may be a transformer.

In another aspect, a monitoring apparatus is configured to: receive measured data from an electrical apparatus; determine a load forecast based on the measured data; determine whether a pre-determined time interval has elapsed; and after the pre-determined time interval has elapsed: estimate an actual amount of life lost for the insulation during the pre-determined time interval that elapsed based on the measured data; estimate a predicted amount of life lost for the insulation during one or more future time intervals based on the load forecast; and estimate a remaining service life for the electrical apparatus based on the actual amount of life lost and the predicted amount of life lost.

Implementations of any of the techniques described herein may be a system, a method, or executable instructions stored on a machine-readable medium. The details of one or more implementations are set forth in the accompanying drawings and the description below. Other features will be apparent from the description and drawings, and from the claims.

### DRAWING DESCRIPTION

FIG. 1 is a block diagram of an example of a system.

FIG. 2 is a block diagram of another example of a system.

FIG. 3 is a block diagram of an example of a monitoring scheme.

FIG. 4 is a flow chart of an example of a process for determining the overload capability of an electrical asset.

FIG. 5 shows predicted hotspot temperature in Celsius (° C.) as a function of time in hours for each of a range of load factors for a simulated transformer.

FIG. 6 is a contour plot of predicted overload capability for the same simulated transformer as FIG. 5, with time (minutes) versus load factor, with the contour lines being the predicted hotspot temperature in ° C.

FIGS. 7A-7C are a flow chart of an example of a process for estimating the remaining life of an electrical asset that includes insulation.

### DETAILED DESCRIPTION

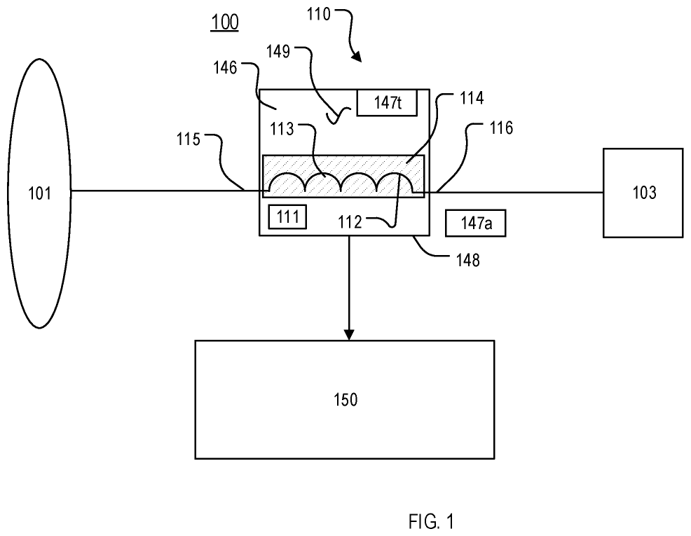

FIG. 1 is a block diagram of an example of a system 100 that includes an alternating current (AC) electrical power grid 101. A single phase is shown in FIG. 1 for simplicity. However, the power system 100 may be a multi-phase (for example, three-phase) power system. The electrical power system 100 includes an electrical asset 110 and a monitoring apparatus or monitoring system 150. As discussed below, the monitoring system 150 allows efficient operation of the electrical asset 110. For example, the monitoring system 150 determines an overload capability of the electrical asset 110, a remaining lifetime of the electrical asset 110, and/or a load forecast for the electrical asset 110.

The electrical asset 110 is any type of electrical equipment that includes one or more electrically conductive windings or coils and is configured for use in an AC electrical power system. For example, the electrical asset 110 may be a transformer, a voltage regulator, or an inductor. The electrical asset 110 may be a three-phase electrical asset.

The electrical asset 110 has a rated load, which is determined from the nominal voltage output of the electrical asset 110 at the maximum deliverable current that the electrical asset 110 is designed to conduct. The rated load may be expressed in units of volt-amperes (VA). The rated load may be included on a nameplate 111 of the electrical asset 110 and/or otherwise associated with the electrical asset 110. The electrical asset 110 is overloaded when the rated load is exceeded. The amount of overloading may be characterized relative to the rated load using a load factor, which is the ratio of the present load to the rated load. For example, operating the electrical asset 110 at the rated load is a load factor of 1, and operating the electrical asset such that it operates at a volt-ampere amount that is 10% greater than the rated load is a load factor of 1.1. Uncontrolled overloading of the electrical asset 110 may result in accelerated aging of the electrical asset 110. For example, overloading may degrade insulation 114 and cause the insulation 114 to fail prior to its expected lifetime. Thus, legacy systems tend to be operated in a manner that avoids overloading.

As discussed in greater detail below, the monitoring system 150 is configured to estimate a remaining service lifetime of the electrical asset 110 based on historical load factor and/or a forecasted future load factor instead of relying on assumed or default loading. Alternatively or additionally, the monitoring system 150 is configured to determine a load factor and an associated time period that allows the electrical asset 110 to be intentionally overloaded in a safe manner. In this way, the monitoring system 150 allows the electrical asset 110 to be used to its fullest extent and also reduces the chance that the electrical asset 110 is taken out of service earlier than necessary.

Before discussing the monitoring system 150 in greater detail, an overview of the AC power grid 101 and the electrical asset 110 is provided.

The AC power grid 101 is a three-phase power grid that operates at a fundamental frequency of, for example, 50 or 60 Hertz (Hz). The power grid 101 includes devices, systems, and components that transfer, distribute, generate, and/or absorb electricity. For example, the power grid 101 may include, without limitation, generators, power plants, electrical substations, transformers, renewable energy sources, transmission lines, reclosers and switchgear, fuses, surge arrestors, combinations of such devices, and any other device used to transfer or distribute electricity.

The power grid 101 may be low-voltage (for example, up to 1 kilovolt (kV)), medium-voltage or distribution voltage (for example, between 1 kV and 35 kV), or high-voltage (for example, 35 kV and greater). The power grid 101 may include more than one sub-grid or portion. For example, the power grid 101 may include AC micro-grids, AC area networks, or AC spot networks that serve particular customers. These sub-grids may be connected to each other via switches and/or other devices to form the grid 101. Moreover, sub-grids within the grid 101 may have different nominal voltages. For example, the grid 101 may include a medium-voltage portion connected to a low-voltage portion through a distribution transformer. All or part of the power grid 101 may be underground.

The load 103 may be any device that uses, transfers, or distributes electricity in a residential, industrial, or commercial setting, and the load 103 may include more than one device. For example, the load 103 may be a motor, an uninterruptable power supply, or a lighting system. The load 103 may be a device that connects the electrical asset 110 to another portion of the power grid 101. For example, the load 103 may be a recloser or switchgear, another transformer, or a point of common coupling (PCC) that provides an AC bus for more than one discrete load. The load 103 may include one or more distributed energy resources (DER). A DER is an electricity-producing resource and/or a controllable load. Examples of DER include, for example, solar-based energy sources such as, for example, solar panels and solar arrays; wind-based energy sources, such as, for example wind turbines and windmills; combined heat and power plants; rechargeable sources (such as batteries); natural gas-fueled generators; electric vehicles; and controllable loads, such as, for example, some heating, ventilation, air conditioning (HVAC) systems and electric water heaters.

The electrical asset 110 includes a housing 148 that defines an interior space 149. The housing 148 may be any solid, durable material, such as, for example, steel. In some implementations, the housing 148 is sealed and the interior space 149 contains a fluid 146. The fluid 146 may be, for example, a gas such as air, or a liquid such as oil. The fluid 146 may be an electrically insulating liquid, such as, for example, mineral oil, petroleum oil, vegetable oil, and/or synthetic fluids; or an electrically insulating gas. The electrical asset 110 includes a winding 112 in the interior space 149. The electrical asset 110 also includes a sensor 147t in the interior space 149 and a sensor 147a exterior to the housing 148. The sensors 147t and 147a are thermal sensors that measure, respectively, a temperature in the interior space 149 and an ambient temperature of the environment that surrounds the electrical asset 110.

The electrical asset 110 has a first side 115 and a second side 116. In the example of FIG. 1, the first side 115 is electrically connected to an AC power grid 101 and the second side 116 is electrically connected to a load 103. Electrical power from the AC power grid 101 is delivered to the load 103 through the winding 112. In some implementations, the electrical asset 110 is configured to allow bi-directional power flow such that electrical power is also delivered from the load 103 to the grid 101 through the winding 112. In implementations in which the electrical asset 110 is a transformer, the first side 115 and the second side 116 may be referred to as the primary side 115 and the secondary side 116, respectively. The first side 115 may be referred to as an input side 115 and the second side 116 may be referred to as an output side 116.

The winding 112 is made of an electrically conductive material, such as a metal, and is shaped into a coil that includes turns 113. In the example shown in FIG. 1, the winding 112 includes many turns but only one turn is labeled for simplicity. The winding 112 may have any configuration and arrangement that is suitable for the application. For example, the winding 112 may be a copper wire wound in a helix shape or a copper wire wound around a core, such as a ferromagnetic annulus.

The electrical asset 110 also includes insulation 114 (shown with diagonal striped shading in FIG. 1). The insulation 114 electrically insulates the turns 113 from each other and also may electrically insulate the winding 112 from other parts of the electrical asset 110. The insulation 114 also may mechanically support the winding 112 and/or protect the winding 112 from contamination.

The insulation 114 may be directly attached to the winding 112. For example, the insulation 114 may be an electrically insulating coating that is applied to the outer surface of the winding 112. Examples of this type of insulation 114 include, without limitation, resin, epoxy, varnish, and polymer coatings or claddings. The insulation 114 may be an electrically insulating material that is separate from the winding 112 and does not necessarily make contact with the winding 112. Examples of this type of insulation 114 include, without limitation, physical barriers, such as, for example, clamps, boards, and/or spacers made of electrically insulating material, such as, for example, polymer foam or polymer sheets. The insulation 114 may include a combination of such materials. For example, the winding 112 may be coated with a resin and surrounded by an electrically insulating hardened foam.

When the load on the electrical asset 110 increases, the amount of heat dissipated from the winding 112 increases and is transferred to the insulation 114. This heating degrades the material that forms the insulation 114. For example, heating the insulation 114 may weaken the mechanical strength of the insulation 114 such that the insulation 114 is unable to withstand the force caused by a fault current passing through the winding 112. The thermal degradation of the insulation 114 is irreversible and may cause the insulation 114 to fail before the end of its nominal lifetime. Prolonged overloading and the corresponding reduction in lifetime of the insulation 114 due to thermal degradation is a main cause of failure of the electrical asset 110, and replacement of the insulation 114 without replacement of the entire electrical asset 110 is generally not feasible. Thus, the lifetime of the insulation 114 generally determines the lifetime of the electrical asset 110.

As discussed above, the amount of thermal exposure the insulation 114 experiences depends on the loading of the electrical asset 110. However, according to the traditional approach, the electrical asset 110 is assumed to have been operated under constant load and it is also assumed that the electrical asset 110 will be operated under constant load for the remainder of its life. Moreover, the traditional approach assumes a fixed lifetime of the insulation 114. On the other hand, the monitoring system 150 observes the loading of the electrical asset 110 over time. The monitoring system 150 uses the historical load on the electrical asset 110 and/or the forecasted load on the electrical asset 110 to estimate the remaining life of the insulation 114 (and thus the remaining life of the electrical asset 110). By using information related to the historical load and/or the forecasted load, the monitoring system 150 provides a more realistic remaining life prediction for the electrical asset 110 than the traditional approach. Additionally, the monitoring system 150 is able to provide a more accurate estimate of the overloading capacity and maximum load of the electrical asset 110.

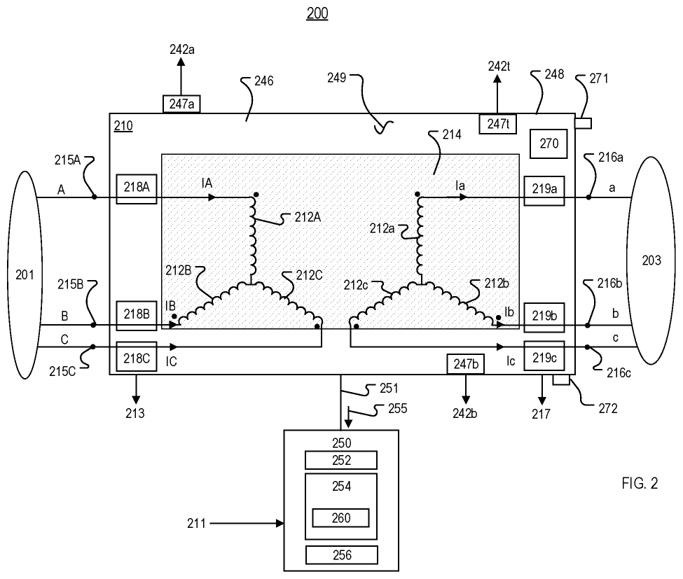

FIG. 2 is a block diagram of a system 200. The system 200 includes an electrical asset 210 and a monitoring system 250. The electrical asset 210 is a three-phase, wye-wye connected transformer that is cooled with a fluid 246, such as, for example, a synthetic or natural oil. Other configurations of the electrical asset 210 are possible, and the three-phase, wye-wye connected transformer is provided as an example.

The transformer 210 includes a housing 248 that defines an interior region 249. The interior region 249 contains the fluid 246. The fluid 246 may be circulated in the interior region 249 by a thermal management system 270. The thermal management system 270 includes any type of device that is capable of moving the fluid 246. For example, the thermal management system 270 may include a pump, a fan, a tube, and/or a combination of such devices. The thermal management system 270 is shown as being in the interior region 249 but all or part of the thermal management system 270 may be outside of the housing 248.

The transformer 210 also includes a fluid inlet 271 and a fluid outlet 272, both of which are in fluid communication with the interior region 249. The fluid 246 is introduced into the interior region 249 through the fluid inlet 271 and is removed from the interior region 249 through the fluid outlet 272.

The transformer 210 includes thermal sensors 247t, 247b in the interior region 249. The thermal sensors 247t and 247b may be any type of thermal sensor, such as, for example, a thermocouple. The thermal sensor 247t produces a top fluid temperature indication 242t, which is an indication of the temperature of the fluid 246 at or near the inlet 271. A thermal sensor 247a is positioned to measure the ambient temperature in the environment that is exterior to the interior region 249. For example, the thermal sensor 247a may be mounted on the housing 248 or next to the exterior of the housing 248. In some implementations, the thermal sensor 247a is placed in the vicinity of the housing 248. For example, the thermal sensor 247a may be positioned at a distance of 1 meter or more from the exterior of the housing 248. The thermal sensor 247a produces an ambient temperature indication 242a, which is an indication of the temperature of the environment that surrounds the transformer 210. The thermal sensor 247a may be any kind of sensor that is capable of measuring temperature. For example, the thermal sensor 247a may be a thermocouple or a thermometer. In some implementations, the thermal sensor 247a is part of a weather station that produces meteorological data in addition to providing temperature data.

The transformer 210 includes two windings per phase in the interior region 249, as follows: a primary winding 212A and a secondary winding 212a in the A phase, a primary winding 212B and a secondary winding 212b in the B phase, and a primary winding 212C and a secondary winding 212c in the C phase. The transformer 210 also includes electrical insulation 214 (show in gray diagonal striped shading) that protects the primary and secondary windings. The electrical asset 210 has first nodes 215A, 215B, 215C and second nodes 216a, 216b, 216c. The first nodes 215A, 215A, 215C are electrically connected to phases A, B, C of an AC power grid 201. The AC power grid 201 distributes AC current that has a fundamental frequency. The second nodes 216a, 216b, 216c are connected to phases a, b, c of a load 203.

A primary AC current IA, IB, IC flows in each respective first node 215A, 215B, 215C. A secondary AC current Ia, Ib, Ic flows from each respective second node 216a, 216b, 216c. The transformer 210 may be used to step-up (increase) or step-down (decrease) the amplitude of the secondary currents and voltages relative to the primary currents and voltages. When the number of turns in the primary winding 212A, 212B, 212C is greater than the number of turns in the respective secondary winding 212a, 212b, 212c, the amplitude of the secondary current Ia, Ib, Ic is smaller than the amplitude of the respective primary current IA, IB, IC. When the number of turns in the primary winding 212A, 212B, 212C is less than the number of turns in the respective secondary winding 212a, 212b, 212c, the amplitude of the secondary current Ia, Ib, Ic is greater than the amplitude of the respective primary current IA, IB, IC.

The transformer 210 also includes sensors 218A, 218B, 218C that measure one or more electrical properties at the first nodes 215A, 215B, 215C and sensors 219a, 219b, 219c that measure one or more electrical properties at the second nodes 216a, 216b, 216c. For example, each of the sensors 218A, 218B, 218C, 219a, 219b, 219c may measure current, voltage, and/or power at the respective nodes 215A, 215B, 215C, 216a, 216b, 216c. The sensors 218A, 218B, 218C, 219a, 219b, 219c may be any kind of electrical sensor, for example, current transformers (CTs), Rogowski coils, power meters, and/or potential transformers (PT).

The sensors 218A, 218B, 218C produce an indication 213, and the sensors 219a, 219b, 219c produce an indication 217. The indications 213 and 217 include data that represent measured values. For example, the indications 213 and 217 may include sets of numerical values that are each associated with a time stamp, where each set includes three measured values that represent an instantaneous value of an electrical property at one of the first nodes or one of the second nodes. Although the indications 213 and 217 are shown in the example of FIG. 2, other implementations are possible. For example, in some implementations, each sensor 218A, 218B, 218C, 219a, 219b, 219c produces a separate indication.

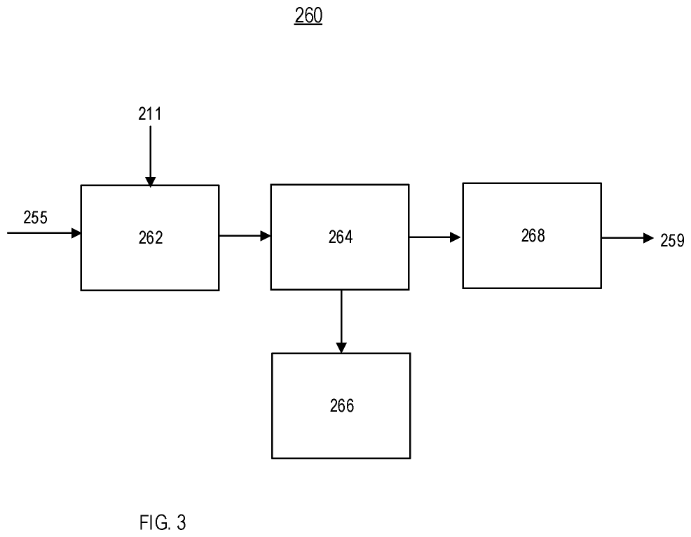

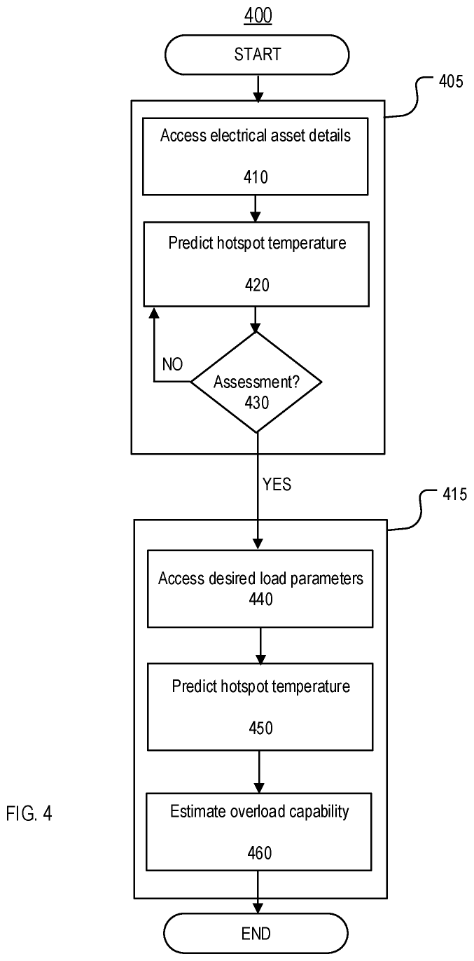

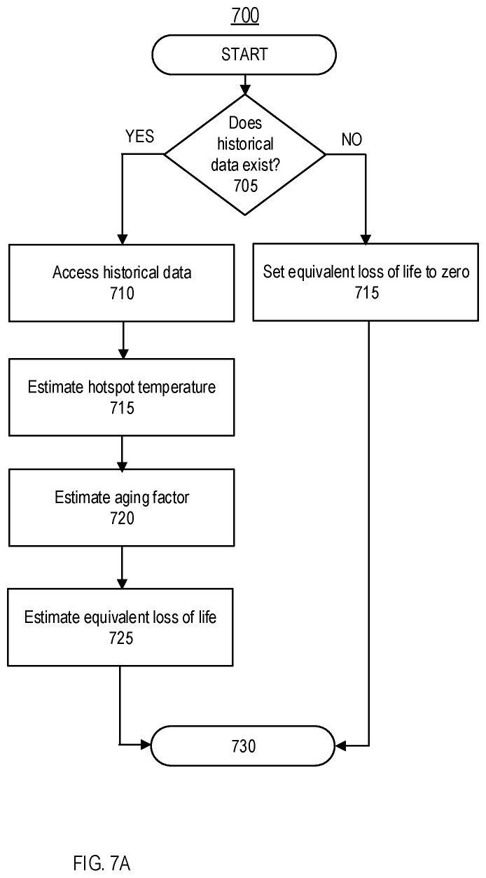

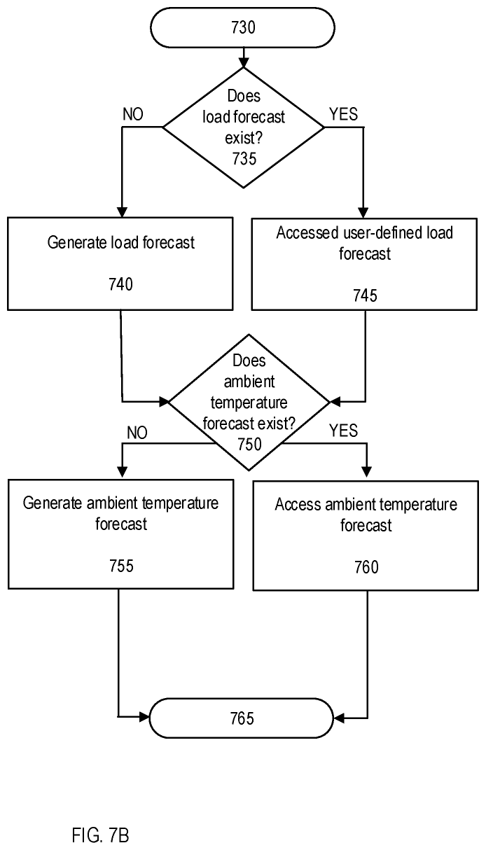

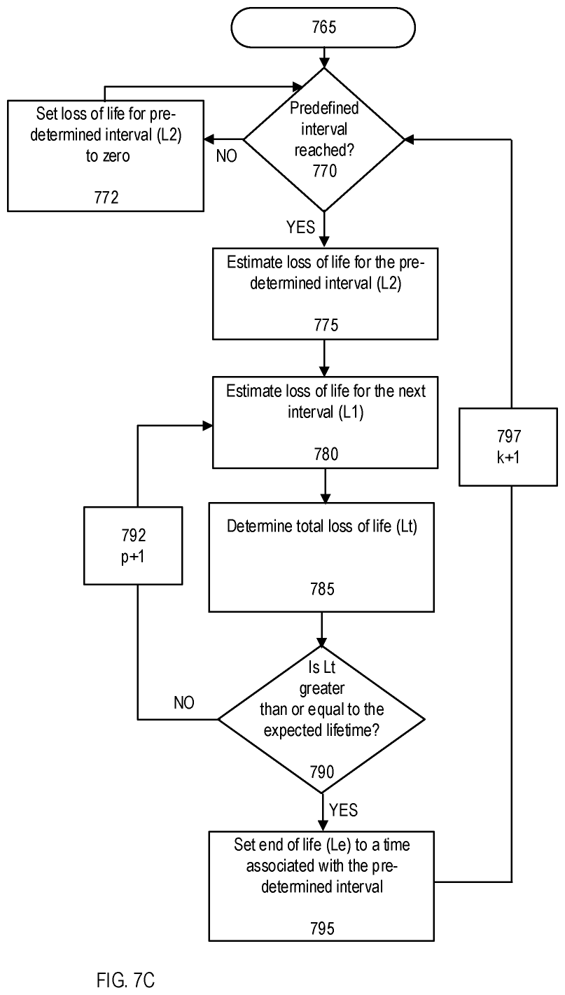

The monitoring system 250 receives measured data 255 as an input. The measured data 255 includes the indications 213 and 217, the top fluid temperature indication 242t, the bottom fluid temperature indication 242b, and the ambient temperature indication 242a. The monitoring system 250 uses the measured data 255 to predict the lifetime of the insulation 214 and the overload capability of the transformer 210, as discussed in greater detail with respect to FIG. 3, FIG. 4, and FIGS. 7A-7C.

The monitoring system 250 includes an electronic processing module 252, an electronic storage 254, and an input/output (I/O) interface 256. The electronic processing module 252 includes one or more electronic processors, each of which may be any type of electronic processor and may or may not include a general purpose central processing unit (CPU), a graphics processing unit (GPU), a microcontroller, a field-programmable gate array (FPGA), Complex Programmable Logic Device (CPLD), and/or an application-specific integrated circuit (ASIC).

The electronic storage 254 is any type of electronic memory that is capable of storing data and instructions in the form of computer programs or software, and the electronic storage 254 may include volatile and/or non-volatile components. The electronic storage 254 and the processing module 252 are coupled such that the processing module 252 can access or read data from and write data to the electronic storage 254.

The electronic storage 254 stores executable instructions, for example, as a computer program, logic, or software, that cause the processing module 252 to perform various operations. The electronic storage 254 includes executable instructions that implement a monitoring scheme 260. Details of an example of an implementation of the monitoring scheme 260 are discussed with respect to FIG. 3.

The electronic storage 254 also may store information about the transformer 210. For example, the electronic storage 254 may store nameplate information 211. The nameplate information 211 may include, for example, the rated temperature of the insulation 214 (or the critical hotspot temperature limit); the rated load of the transformer 210; the number of turns on the windings 212A, 212B, 212C, 212a, 212b, 212c; a voltage and/or current rating of the transformer 210; a heat capacity of the material of the windings 212A, 212B, 212C, 212a, 212b, 212c; an identifier or flag that indicates the electrical configuration of the transformer 210; and/or an arrangement of the bushings on the transformer 210. The critical hotspot temperature limit is the highest temperature that the insulation 214 is designed to tolerate. The nameplate information 211 is loaded onto the electronic storage 254 via the I/O interface 256. For example, an operator may enter the nameplate information 211 while the transformer 210 is in the field. In another example, the manufacturer of the transformer 210 may add or edit the nameplate information 211 via the I/O interface 256.

The I/O interface 256 is any interface that allows a human operator, another electronic device, and/or an autonomous process to interact with the monitoring system 250. The I/O interface 256 may include, for example, a display (such as a liquid crystal display (LCD)), a keyboard, audio input and/or output (such as speakers and/or a microphone), visual output (such as lights and/or light emitting diodes (LED)) that are in addition to or instead of the display, a serial or parallel port, a Universal Serial Bus (USB) connection, and/or any type of network interface, such as, for example, Ethernet. The I/O interface 256 also may allow communication without physical contact through, for example, an IEEE 802.11, Bluetooth, or a near-field communication (NFC) connection. The monitoring system 250 may be, for example, operated, configured, modified, or updated through the I/O interface 256.

The I/O interface 256 also may allow the monitoring system 250 to communicate with systems external to and remote from the monitoring system 250 and the transformer 210. For example, the I/O interface 256 may include a communications interface that allows communication between the monitoring system 250 and a remote station (not shown), or between the monitoring system 250 and a separate electrical apparatus (such as another transformer) using, for example, the Supervisory Control and Data Acquisition (SCADA) protocol or another services protocol, such as Secure Shell (SSH) or the Hypertext Transfer Protocol (HTTP). The remote station may be any type of station through which an operator is able to communicate with the monitoring system 250 without making physical contact with the monitoring system 250. For example, the remote station may be a computer-based work station, a smart phone, tablet, or a laptop computer that connects to the monitoring system 250 via a services protocol or a telephone system, or a remote control that connects to the monitoring system 250 via a radio-frequency signal. The monitoring system 250 may communicate information to an external device through the I/O interface 256.

FIG. 3 is a block diagram of the monitoring scheme 260. The monitoring scheme 260 includes a hotspot temperature block 262, a loss of life block 264, a remaining service life estimation block 266, and an overload capability block 268. The hotspot temperature block 262 estimates the winding hotspot temperature (θ_{H}). The winding hotspot temperature (or hotspot temperature) is an estimate of the highest temperature or maximum temperature of the winding 212. The measured data 255 may include any of the indications 213 and 217, the top fluid temperature indication 242t, the bottom fluid temperature indication 242b, and the ambient temperature indication 242a. The loss of life block 264 estimates the portion of the service life that has passed using the estimate of the hotspot temperature provided by the hotspot temperature block 262. The hotspot temperature block 262 and the loss of life block 264 may be implemented based on the Institute of Electrical and Electronics Engineers (IEEE) C57.91 standard.

The remaining service life estimation block 266 uses the estimate of the hotspot temperature and the measured data 255 to determine a more accurate estimate of the remaining service life of the transformer 210 by accounting for the historical loading and predicted future loading on the transformer 210. The overload capability block 268 produces an estimate 259 of the dynamic overload capability of the transformer 210 and also estimates a loading forecast for the transformer 210.

FIG. 4 is a flow chart of a process 400. The process 400 is an example of a process for determining the overload capability of an electrical asset implemented by the overload capability block 268. The process 400 is implemented as a set of machine-executable instructions that are stored on the electronic storage 254. The process 400 runs during operation of the transformer 210. Although the process 400 may be used to determine the overload capability of any electrical asset, the process 400 is discussed with respect to the transformer 210.

The process 400 includes an initialization section 405 and a prediction section 415. The initialization section 405 is performed until the prediction section 415 starts. The prediction section 415 may start in response to a request to estimate the overloading capability of the transformer 210.

In the initialization section 405, one or more details of the transformer 210 are accessed (410). The one or more details of the transformer 210 may include the critical hotspot temperature limit, which is the maximum or rated temperature of the insulation 214, and details about the winding 212, such as the specific heat of the winding and the mass of the winding 212.

The critical hotspot temperature limit may be accessed from the electronic storage 254 and/or from the I/O interface 256. The critical hotspot temperature limit may be part of the nameplate information 211. The electrical asset details also include the measured data 255.

The hotspot temperature is predicted (420) based on the accessed details of the transformer. The hotspot temperature at a particular time is predicted or estimated using various equations that are set forth in the IEEE 57.91 Standard, Annex G. The hotspot temperature at a particular time (time t2 in the example below) is estimated using Equation 1:

$${Θ}_{H , 2} = \frac{{Q}_{gen , HS} - {Q}_{Lost , HS} + {M}_{W} {C}_{PW} {Θ}_{H , 1}}{{M}_{W} {C}_{PW}} , \qquad Equation ( 1 )$$

where θ_{H,2} is the hotspot temperature at time t2; θ_{H,1} is the hotspot temperature at time t1 (where t1 is a time that occurred prior to time t2); Mw is the mass of the winding 212; C_{PW} is the specific heat of the winding 212; Q_{gen,Hs} is heat generated at the hotspot temperature; and Q_{lost,HS} is the heat load at the hotspot temperature. The Q_{gen,Hs} is estimated as shown in Equation (2):

$${Q}_{gen , HS} = {K}^{2} [ {P}_{HS} {K}_{HS} + \frac{{P}_{EHS}}{{K}_{HS}} ] Δ t , \qquad Equation ( 2 )$$

where K is the load factor (or the present load divided by the rated load), P_{HS} is the copper loss at rated load and rated winding hotspot temperature, K_{HS} is the temperature correction for losses at the hotspot location, P_{EHS} is the eddy current loss at rated load and rated winding hotspot temperature, and Δt is the time difference between t2 and t1. The time difference between t2 and t1 is also referred to as the time step. The value of K is calculated by determining the present load using the indication 217 (which is the measured current output by the transformer 210) and dividing the calculated present load by the rated load of the transformer 210. The value of Δt may be stored on the electronic storage 254. The initial value of the prior hotspot temperature (θH,1) when the transformer 210 is first operated at time=0 may be set to 0 or to a predefined value that is stored on the electronic storage 254.

The value of Qlost,HS is estimated as shown in Equation (3):

$$QLost , HS = {{[ \frac{{Θ}_{H , 1} - {Θ}_{w 0}}{{Θ}_{H , r} - {Θ}_{w 0 , R}} ]}^{1.25} [ \frac{{μ}_{HS , R}}{{μ}_{HS , 1}} ]}^{0.25} ( {P}_{HS} + {P}_{EHS} ) Δ t , \qquad Equation ( 3 )$$

where θ_{H,R} is the hotspot temperature at rated load; μ_{HS,1} is the viscosity of the fluid 246 for the hotspot temperature at the previous time t1; μ_{HS,R} is the viscosity of the fluid 246 for the hotspot temperature at the rated load; θ_{WO} is the temperature of the fluid 246 adjacent to the winding hotspot at the current time instant (time t2 in this example); and θ_{WO,R} is the temperature of the fluid 246 adjacent to the winding hotspot at the rated load. The value of K_{HS} used in Equation (2) is estimated as shown in Equation (4):

$${K}_{HS} = \frac{{Θ}_{H , 1} + {Θ}_{K}}{{Θ}_{H , R} + {Θ}_{K}} , \qquad Equation ( 4 )$$

The values of P_{HS} and P_{EHS}, which are both used in Equation (2), are estimated as shown in Equation (5) and Equation (6):

$$\begin{matrix}{P}_{HS} = ( \frac{{Θ}_{H , R} + {Θ}_{k}}{{Θ}_{W , R} + {Θ}_{k}} ) {P}_{w} \\ and & Equation ( 5 ) \\ {P}_{EHS} = {E}_{HS} {P}_{HS} , & Equation ( 6 )\end{matrix}$$

where θ_{W,R} is the average temperature of the winding 212 at the rated load, Ok is the temperature factor for resistance correction, Pw is the material loss of the winding 212 at the rated load, and E_{HS} is the eddy loss at the winding hotspot location, per unit of material loss.

As shown in Equation (3), the value of Q_{LOST,HS} also depends on the temperature of the fluid 246 adjacent to the winding hotspot (θ_{WO}). Estimation of the fluid 246 temperature adjacent to the winding hotspot (θ_{WO}) is discussed next with respect to Equations (7) to (12). The ambient temperature measured by the sensor 247a is used to determine the heat lost by the fluid 246 due to the ambient conditions outside of the housing 248:

$$QLOST , O = {[ \frac{{Θ}_{AO , 1} - {Θ}_{A , 1}}{{Θ}_{AO , R} - {Θ}_{A , R}} ]}^{\frac{1}{y}} {P}_{T} Δ t , \qquad Equation ( 7 )$$

where θ_{AO,R} is the average temperature of the fluid 246 at the rated load; θ_{AO,1} is the average temperature of the fluid 246 at the prior time t1; θ_{A,1} is the ambient temperature at the prior time t1; θ_{A,R} is the rated ambient temperature at kVA base for the load cycle; P_{T} is the total loss at the rated load in watts; and y is the exponent of average fluid rise with heat loss. The exponent y is 0.8 for an oil natural air natural (ONAN) transformer, and 0.9 for an oil natural air forced (ONAF) or oil forced air forced (OFAF) transformer, and 1.0 for an oil directed air forced (ODAF) transformer.

The heat lost to ambient (Q_{LOST,O}) is used to estimate the average temperature of the fluid 246 at the time t2 (θ_{AO,2}) by:

$${Θ}_{AO , 2} = \frac{{Q}_{LOST , W} + {Q}_{S} + {Q}_{C} - {Q}_{LOST , O} + ( Σ {MC}_{P} ) {Θ}_{AO , 1}}{Σ {MC}_{P}} , \qquad Equation ( 8 )$$

where Q_{LOST,W} is the heat lost by the winding in watts-minute; Qs is the heat generated by stray losses in watts-minute; Qc is the heat generated by the core in watts-minute; Q_{LOST,O} is determined in Equation (7); and the summation of M_{CP} is the total mass times the specific heat of the fluid 246, the housing 248, and the core in watts-minute.

The temperature rise of the fluid 246 at the top of the housing 248 (as measured by the sensor 247t) over the bottom of the housing 248 (as measured by the sensor 247b) is given by:

$${ΔΘ}_{T / B} = ( {Θ}_{TO} - {Θ}_{BO} ) = [ \frac{{Q}_{LOST , O}}{{P}_{T} Δ t} ] ( {Θ}_{TO , R} - {Θ}_{BO , R} ) , \qquad Equation ( 9 )$$

where θ_{TO} is the temperature of the fluid 246 as measured by the sensor 247t; θ_{BO} is the temperature of the fluid 246 as measured by the sensor 247b; θ_{TO,R} is the top fluid 246 temperature at the rated load; and θ_{BO,R} is the bottom fluid 246 temperature at the rated load. Rearranging and combining terms to provide an estimate of the bottom fluid 246 temperature:

$${Θ}_{BO} = {Θ}_{AO} - \frac{{ΔΘ}_{T / B}}{2} . \qquad Equation ( 10 )$$

The bottom fluid 246 temperature is used to find the temperature of the fluid 246 adjacent to the winding (θ_{WO}) based on:

Δθ_{WO/BO}=H_{HS}(θ_{TDO}−θ_{BO}) Equation (11),

where Δ_{WO/BO} is the temperature rise of the fluid 246 at the winding hotspot over the bottom fluid 246 temperature; H_{HS} is the per unit of winding height to hotspot location; and θ_{TDO} is the fluid temperature at the inlet 271. The temperature of the fluid 246 adjacent to the winding is determined by:

θ_{WO}=θ_{BO}+Δθ_{WO/BO} Equation (12).

The temperature of the fluid 246 adjacent to the winding hotspot is used to calculate the heat loss at the hotspot location (Q_{LOST,HS}) as shown in Equation (3), and the heat loss at the hotspot location (Q_{LOST,HS}) is used to estimate the hotspot temperature (θ_{H,2}) as shown in Equation (1).

After each estimation of the hotspot temperature (θ_{H,2}), the process 400 advances to (430) to determine whether a condition to perform a load capability assessment has been met. In other words, the hotspot temperature θ_{H,2} is repeatedly estimated at each time step using (420) during operation of the transformer 210 until the condition to perform a load capability assessment is met.

The condition for performing a load capability assessment may be an elapsed time since the transformer 210 was commissioned or first operated, or the condition may be receipt of a command to perform the load capability assessment. In implementations in which the condition is time-based, the occurrence of the condition may be determined by comparing the elapsed time since the previous load capability assessment or from the beginning of operation of the transformer 210 to a time value stored on the electronic storage 254.

The time value may be input by a user or operator of the transformer 210. For example, the time value may be a numerical value that represents the number of hours that the transformer 210 should be operated before performing the load capability assessment. The numerical value may be, for example, 15 hours, 30 hours, or 100 hours. The numerical value may represent the time elapsed since the installation or initial use of the transformer 210 or the time elapsed since the most recent load capability assessment.

In some implementations, the condition for performing a load capability assessment occurs upon receipt of an external command instead of or in addition to the expiration of a pre-set amount of operating time. For example, an operator or end user of the transformer 210 may enter a request to perform a load capability assessment through the I/O interface 256. The request may be a request to begin the load capability assessment immediately or to begin the load capability assessment after a specified amount of time.

The above conditions for performing a load capability assessment are provided as examples, and other conditions are possible. In some implementations, the condition for performing a load capability assessment is based on the measured data 255. For example, the condition for performing a load capability assessment may occur when the measured current in the indication 217 exceeds the rated current for the transformer for more than a specified amount of time.

If the condition for performing a load capability assessment is not met or has not occurred, the process 400 returns to (420) and predicts the hotspot temperature at the next time step. If the condition for performing a load capability assessment is met, the process 400 continues to the prediction section (415) to perform the load capability assessment.

The desired load parameters are accessed (440). The desired load parameters are parameters that indicate a load factor for operating the transformer 210. The desired load parameters also may include a time duration for operating the transformer at a particular load factor. The desired load parameters may be stored on the electronic storage 254 or entered through the I/O interface 256.

The hotspot temperature is predicted for each load factor in the desired load parameters (450). The hotspot temperature is predicted using Equations (1) to (12). The initial value of (θH,1) is the value of (θH,2) that was determined at (420). The value of K in Equation (2) is set to each of the load factors in the desired load parameters, such that Qgen,HS is determined for each load factor for the time step Δt. The determined values of Qgen,HS are then used in Equation (1) to predict the hotspot temperature θH,2 that would occur if the transformer was operated at the desired load factor for the amount of time represented by Δt. The calculations represented by Equations (1) to (12) may be repeated to predict the hotspot temperature for each load factor for additional time steps, thus predicting the hotspot temperature further into the future. The predicted hotspot temperatures are stored on the electronic storage 254. For example, the estimated hotspot temperature for each load factor at each time step may be stored as a numerical vector or a matrix. The hotspot temperature for each load factor at times that are between the time steps may be estimated by interpolation.

The overload capability of the transformer 210 is estimated (460). The overload capability is estimated based on the hotspot temperature predictions made in (450). For example, the amount of time that the transformer 210 can be operated at a particular load factor is determined by finding the time at which the hotspot temperature for that load factor exceeds the critical hotspot temperature or the specified hotspot temperature. In this example, the overload capability is output as an amount of time for a known or desired load factor. In another example, the overload capability is provided as a maximum load factor at which the transformer 210 may be operated before reaching the critical hotspot temperature or specified hotspot temperature. The overload capability may be presented at the I/O interface 256 and/or transmitted to a remote device as the output 259 (FIG. 3).

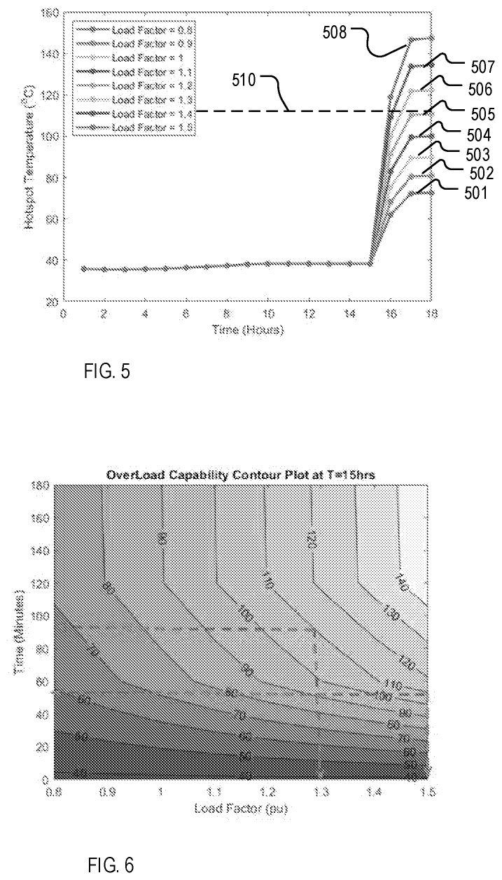

In some implementations, the overload capability is presented graphically. FIGS. 5 and 6 show examples of graphical overload capability computed in (460). FIGS. 5 and 6 show simulated data for a transformer rated at 2.6 MVA, 11 kV/433V with a specified hotspot temperature of 110 degrees Celsius (° C.), which is labeled as 510 in FIG. 5. In this example, the desired load parameters were a range of load factors between 0.8 per unit load (pu) and 1.5 pu in 0.1 increments, and the overload capability was requested 15 hours after the transformer began operating. The load factor is a value that represents a ratio between the current or observed load and the rated load. Thus, a load factor of 1 pu indicates that the transformer 210 is operating at the rated load, a load factor of less than 1 pu indicates that the transformer 210 is operating at less than the rated load, and a load factor of more than 1 indicates that the transformer 210 is operating at more than the rated load.

FIG. 5 shows predicted hotspot temperature in Celsius (° C.) as a function of time in hours for each of the range of load factors in a vector K′=0.8, 0.9, 1.0, 1.1, 1.2, 1.3, 1.4, 1.5. The predicted hotspot temperatures for the load factors in the vector K′ as a function of time are labeled in FIG. 5 as 501, 502, 503, 504, 505, 506, 507, 508, respectively. The predicted hotspot temperature shown in FIG. 5 was determined from Equations (1) through (12), and the load factor (K) was varied in Equation (2) to obtain the predicted hotspot temperature for each load factor. The overload capability condition was met at 15 hours after the transformer 210 began operation, the time step Δt was 1 hour, and the predicted hotspot temperature was computed for three subsequent times: 16 hours, 17 hours, and 18 hours.

As shown in FIG. 5, the predicted hotspot temperature increased as the load factor increased. The load factors of 1.3 and less did not exceed the specified hotspot temperature between 15 and 18 hours. Thus, the simulated transformer can be operated at load factors of 1.3 or less for 3 hours beginning at 15 hours. The process 400 may output the data shown in FIG. 5 as a graph, as a summary of the overload capability (for example, a text or audible message that states that the simulated transformer can be operated at a load factor of up to 1.3 for 3 hours), or the data shown in FIG. 5 may be saved to the electronic storage 254 for later analysis.

FIG. 6 is a contour plot of overload capability for the same simulated transformer, with time (minutes) versus load factor, with the contour lines being the predicted hotspot temperature in ° C. The contour plot in FIG. 6 was generated based on data generated for FIG. 5. The specified hotspot temperature was 110° C. Thus, the contour for the 110° C. is a boundary for safe overloading of the simulated transformer and may be used to determine the overload capability for the simulated transformer. The simulated transformer can be operated safely at any of the load factors and times to the left and below the 110° C. contour line.

FIGS. 7A-7C are a flow chart of a process 700. The process 700 is an example of a process for estimating the remaining life of an electrical asset that includes insulation, such as the electrical asset 110 or the transformer 210. The lifetime of the electrical asset is largely determined by the lifetime of the insulation. Traditional approaches for determining remaining lifetime of an electrical asset assume that the insulation has a useable lifetime of 180,000 hours (about 20.55 years). This estimated insulation lifetime assumes that the electrical asset is loaded in a manner that results in a constant hotspot temperature of 110° C. However, in actual use, the electrical asset experiences a variable load and the hotspot temperature also varies. Thus, the actual lifetime of the insulation (and the electrical asset) may be shorter or longer than the assumed lifetime of 180,000 hours. The process 700 takes the variable nature of the loading of the electrical asset into account to provide a more accurate estimate of the remaining lifetime. By providing a more accurate estimate of the remaining lifetime of the electrical asset, the process 700 allows for more realistic planning for replacement of electrical assets and also promotes efficient use of the electrical assets by allowing the assets to be used beyond their nominal or expected lifetime when possible.

The process 700 may be implemented by a collection of machine-executable instructions that are stored on the electronic storage 254 and form the remaining service life estimation block 266. Although the process 700 may be used to determine the remaining service life of any electrical asset, the process 700 is discussed with respect to the transformer 210.

The process 700 may be initiated in response to a user or operator command and/or after the passage of a predetermined amount of time since the commissioning of the transformer 210. The process 700 initially determines whether historical data exists for the transformer 210 (705). The historical data includes the measured data 255 collected over time during operation of the transformer 210. To determine whether there is historical data, the process 700 may search the electronic storage 254 for the data and/or for a flag or indication that the historical data exists. If there is no historical data, the process 700 advances to (715) and the transformer 210 is assumed to be newly commissioned, newly installed, and/or never previously operated. The elapsed operation time (T) of the transformer 210 is set to zero in this instance, and the initial elapsed life of the insulation 214 (Lo) is zero.

If historical data exists, the historical data is accessed (710). The historical data may be accessed from the electronic storage 254. In some implementations, the historical data is accessed through the I/O interface 256. For example, the electronic storage 254 may store a flag that the historical data exists and a pointer to the location of the historical data. In these implementations, the remaining service life estimation block 266 obtains the historical data from the location via the I/O interface 256. Moreover, in still other implementations, the process 700 may produce a prompt through the I/O interface 256 to request that an operator or end user provide the historical data and/or confirm that no historical data exists prior to determining that no historical data.

The hotspot temperature is estimated based on the historical data (715). The hotspot temperature is estimated by Equations (1) though (12) and the historical load and ambient temperature data.

A corrected aging factor (EQA_{c,M}) is estimated (720). The corrected aging factor is estimated as a sum of a historical aging term that is based on historical data and an estimate of a future aging term. Equation (13) is not part of the IEEE C57.11 standard. Specifically, the EQA_{c,M} is determined using Equation (13):

$${EQA}_{c , M} = \frac{{\sum }_{n = 1}^{N} {w}_{HI , n} {FAA}_{n} Δ {t}_{n}}{{\sum }_{n = 1}^{N} Δ {t}_{n}} + \frac{{\sum }_{m = N + 1}^{M} {w}_{HI , N} {w}_{age , m} {FAA}_{m} Δ {t}_{m}}{{\sum }_{m = N + 1}^{M} Δ {t}_{m}} , \qquad Equation ( 13 )$$

where the first term to the right of the equal sign is the historical term and the second term is the estimate of future aging. In Equation (13), EQA_{c,M} is the equivalent aging factor considering aging and overall health; FAAₙ is the aging acceleration factor for the temperature which exists during the time interval Δtₙ; w_{age,n} is weighting factor for age of operation; W_{HI,n} is weighting factor for overall health index of transformer; WHI,n is a weighting factor for overall health of the monitored electrical asset; n is an integer number that represents the index of the time step; and N is the total number of time steps. W(age,n) is factor related to the age of transformer 210 since it is commissioned or initially operated. The value of W(age,n) is expressed as a percentage incremental. For example, W(age,n) may be 10% incremental. W(HI,n) as calculated from the overall health index of transformer. The health index is a numerical value between 0 to 1. The value of W(HI,n) values depends on the health index. For example, W(HI,n)=1/Health Index.

Also in Equation (13), m is an integer that represents the index of a future time step, and M is the total number of future time steps; FAAₘ is the aging acceleration factor for the temperature which is predicted or expected to exists during the future time interval Δtₘ; w_{age,m} is weighting factor for age of operation; w_{HI,m} is weighting factor for overall health index of transformer; and WHI,N is the weighting factor for overall health of the monitored electrical asset based on data collected over the total historical time period (N).

The aging acceleration factor (FAA) for the temperature that exists during the nth time step Δtn is calculated according to an equation from the IEEE C57.91 standard, shown as Equation (14):

$$FFAn = {e}^{[ \frac{B}{Θ rated} - \frac{B}{Θ estimated} ]} , \qquad Equation ( 14 )$$

where B is 15000, θrated is the critical hotspot temperature for the insulation 214 (for example, 110° C.), and θestimated is the estimated or predicted hotspot temperature for the nth time step. The value of FFAn is determined based on the historical data rather than assuming that the value of the hotspot temperature remains constant.

The initial elapsed life (Lo) of the insulation 214 is estimated (725) based on Equation (15):

Lo=(EQA_{c,M})T Equation (15),

where T is the time that the transformer 210 has been operated and EQA_{c,M} is the corrected aging factor determined in Equation (13). As discussed above, if the transformer 210 is newly commissioned, T=0 and Lo is equal to zero.

Referring to FIG. 7B, next the process 700 determines the remaining service life of the insulation 214 based on forecasted data. Whether or not a load forecast exists (735) is determined. A load forecast is data that specifies the expected future loading of the transformer 210. The load forecast is defined by a user or operator of the transformer 210. If the electronic storage 254 includes data that specifies the expected future loading, then a load forecast exists and the user-defined load forecast data is accessed (745). If a load forecast does not exist, then a load forecast is generated (740). The load forecast may be generated based on load data measured during prior operation of the transformer 210 (before the time T occurred). For example, measured current and voltage data from the sensors 219a, 219b, 219c may be saved on the electronic storage 254 and used to determine the actual load on the transformer 210 over time. This historical load data may be used to generate a representative load cycle over a time step. For an implementation in which the time step is a year, the representative load cycle may be, for example, the average yearly load on the transformer 210 determined by averaging the load on the transformer 210 for each year that occurred between the time of commissioning and the time T.

Next, it is determined whether or not a pre-defined ambient temperature forecast exists (750). A pre-defined ambient temperature forecast is data that defines expected temperatures in the environment outside of the housing 248. For example, the pre-defined ambient temperature forecast may include temperature data entered by the end-user or the operator of the transformer 210. The weather data entered by the end-user or the operator may include temperatures that are each associated with a time in the future or an average temperature that the end-user or operator expects to occur in the future. If a pre-defined ambient temperature forecast exists, the forecast is accessed (760).

If a pre-defined ambient temperature forecast does not exist, an ambient temperature forecast is generated (755). The ambient temperature forecast may be generated based on temperature data measured by the thermal sensor 247a during a similar time period. For example, the ambient temperature forecast may be set to the average temperature measured by the thermal sensor 247a from the time at which the transformer 210 was commissioned to the time T, or an average over all of the prior time steps or historical data found during similar time periods. In some implementations, the ambient temperature forecast is generated by obtaining weather station or a forecast from a weather forecasting service.

Next, the process 700 estimates the loss of life of the insulation 214 using the forecasted load and temperature data at a plurality of future times to estimate when the insulation 214 will fail by determining two other loss of life (or elapsed life) metrics: L1 and L2, as discussed below.

Referring to FIG. 7C, the transformer 210 continues to operate and the monitoring system 250 continues to receive the measured data 255, and the process 700 determines if a pre-defined temporal has been reached (770). For example, if the pre-defined interval is 1 year, the pre-defined temporal interval is reached at T+k*(1 year), where k is an integer number that represents the index number of the current temporal interval and T is the amount of time between initial operation of the transformer 210 and the time at which the initial elapsed life (Lo), as discussed above with respect to Equation (15). If the time corresponding to the kth pre-defined temporal interval has not yet occurred, the value of the loss of life (L2) is set to zero (772). The monitoring system 250 continues to collect the measured data 255, time passes, and the process 700 returns to (770) to determine if the kth pre-determined interval has been reached.

If the pre-defined temporal interval has been reached, L2, which is the amount of insulation 214 life loss that occurred in the current pre-determined interval, is estimated (775). Because the kth pre-defined temporal interval has occurred, the monitoring system 250 has received the measured data 255 for the kth pre-defined temporal interval. Thus, the loss of life (L2) for the time period encompassed by the kth pre-determined time interval is estimated using the actual load and thermal data measured during the kth pre-determined interval. The loss of life (L2) is estimated using the actual load and thermal data in Equations (13) and (14) and then determining L2 based on Equation 16:

L2=(EQA_{c,M})Tₖ Equation (16),

where Tk is the time duration for the kth pre-defined time interval.

The loss of life for the forecasted load (L1) is determined using the load and thermal forecasts for the kth+1 time interval (780). The kth+1 time interval has not yet occurred, thus the forecasted data is used. In the discussion below, the time intervals associated with future time intervals are indexed with p, where the initial value of p is equal to k+1. Thus, p tracks the future time intervals that have not yet occurred beginning with the interval that is associated with k+1. The loss of life (L1) is estimated using the forecasted load and thermal data in Equations (13) and (14) and then determining L1 based on Equation 17:

L1ₚ=L1ₚ₋₁+(EQA_{c,M})Tₚ Equation (17),

where Tp is the time duration for the pth pre-defined time interval, and L1(p−1) is the value of L1 determined for the prior pre-defined time interval, with L1(0) being equal to zero.

The total loss of life (Lt) for the mth pre-defined time interval is determined (785). The total loss of life (Lt) is determined based on Equation (18):

Lt=Lo+L2+L1 Equation (18),

where Lo is the estimated loss of life for the time period between the initial use of the transformer 210 and the time T, L2 is the loss of life for the kth time interval, and L1 is the loss of life for the pth time interval. Lo and L2 are estimated on measured data 255, and L1 is based on forecasted load and thermal data.

The value of Lt is compared to the expected lifetime of the insulation 214 (790). The expected lifetime of the insulation 214 is stored on the electronic storage 254 and may be part of the nameplate information 211. The expected lifetime may be, for example, 180,000 hours.

If the value of Lt is less than the expected lifetime, the interval index (p) is increased by one and the process 700 returns to (780). The loss of life for the next interval (L1p+1 in this example) is determined using forecasted load and thermal data for the next temporal interval at (780) and (785). The total loss (Lt) is again determined (790).

Returning to (790), if the total loss of life (Lt) is greater than or equal to the expected lifetime, the estimated end of life (Le) is set to a time that is associated with the current pre-determined interval (795). The time associated with the current pre-determined interval is given by Equation (19):

Le=p(pre-determined time interval)+T Equation (19),

where p is the index number of the last pre-determined temporal index for which the loss of life (L1) was determined and T is the amount of time that elapsed to determine Lo in Equation (15). The value of m represents how many temporal periods into the future have been estimated. For example, if the pre-determined time interval is a year, T is 12 years, and p=5 such that the current pre-determined time interval represents the 5^{th} year after year 12, then the estimated value of Le is 5 years plus 12, or 17 years.

The process 700 increases the value of k (which indexes the pre-determined temporal intervals that actually occur) by one and returns to (770). After the next or subsequent pre-determined temporal interval occurs, the process 700 advances to (775) to determine again L2 based on the actual measured data 255 that the monitoring system 250 received for the pre-determined temporal interval. This value of L2 is used in the determination of Lt at (785). Thus, each time the index k is increased by 1, more actual data is used to determine Lt, thereby improving the accuracy of the estimate Le over time.

These and other implementations are within the scope of the claims.

What is claimed is:

1. A system comprising:
an electrical apparatus comprising:
a housing that defines an interior space;
an active portion in the interior space; and
insulation configured to electrically insulate at least part of the active portion; and
a monitoring apparatus configured to:
receive measured data from the electrical apparatus;
determine a load forecast for the electrical apparatus based on the measured data;
determine whether a pre-determined time interval has elapsed; and
after the pre-determined time interval has elapsed:
estimate an actual amount of life lost for the insulation during the pre-determined time interval that elapsed based on the measured data;
estimate a predicted amount of life lost for the insulation during one or more future time intervals based on the load forecast; and
estimate a remaining service life for the electrical apparatus based on the actual amount of life lost and the predicted amount of life lost.

2. The system of claim 1, wherein the monitoring apparatus is further configured to:
compare the estimated remaining service life to an expected lifetime of the electrical apparatus; and
if the estimated remaining service life is greater than or equal to the expected lifetime:
determine whether a subsequent pre-determined time interval has elapsed;
receive additional measured data from the electrical apparatus;
after the subsequent pre-determined time interval has elapsed, estimate the actual amount of life lost for the insulation during the subsequent pre-determined time interval based on the additional measured data.

3. The system of claim 1, wherein the monitoring apparatus is further configured to estimate an initial amount of life lost for the insulation, wherein the initial amount of life lost is the amount of life lost between an initial use of the electrical asset and an assessment time; and
the remaining service life for the electrical apparatus is estimated based on the actual amount of life lost, the predicted amount of life lost, and the initial amount of life lost.

4. The system of claim 3, wherein the assessment time occurs when a command requesting a service life estimate is received at the monitoring apparatus.

5. The system of claim 3, wherein the assessment time is a pre-defined time period measured from the initial use of the electrical asset.

6. The system of claim 3, wherein the initial amount of life lost is based on measured data associated with times between the initial use of the electrical asset and the assessment time, and an aging factor.

7. The system of claim 1, wherein the active portion comprises one or more electrically conductive coils, and the insulation is configured to electrically insulate the coils.

8. The system of claim 7, wherein the electrical apparatus is a transformer.

9. The system of claim 1, wherein the measured data comprises measurements related to electrical current that flows in the one or more coils.

10. The system of claim 1, wherein the measurements comprise numerical values that represent any of current, voltage, and power.

11. A system comprising:
an electrical apparatus comprising:
a housing that defines an interior space;
an active portion in the interior space; and
insulation configured to electrically insulate at least part of the active portion; and
a monitoring apparatus configured to:
access one or more desired load parameters related to future operation of the electrical asset;
predict a hotspot temperature of the insulation based on each of the one or more desired load parameters; and
estimate an overload capability of the electrical asset based on the predicted hotspot temperature, wherein the overload capability comprises at least one desired load factor and a time duration during which the electrical asset is capable of being operated at the determined load factor.

12. The system of claim 11, wherein the monitoring apparatus is further configured to determine an initial hotspot temperature prior to predicting the hotspot temperature of the insulation based on each of the desired load parameters.

13. The system of claim 11, wherein the one or more desired load parameters comprise one or more desired load factors, wherein each desired load factor represents a ratio between a requested load of the electrical asset and a rated load of the electrical asset.

14. The system of claim 13, wherein at least one of the desired load factors is greater than 1.

15. The system of claim 11, wherein the electrical asset is a transformer.

16. A monitoring apparatus configured to:
receive measured data from an electrical apparatus;
determine a load forecast based on the measured data;
determine whether a pre-determined time interval has elapsed; and
after the pre-determined time interval has elapsed:
estimate an actual amount of life lost for the insulation during the pre-determined time interval that elapsed based on the measured data;
estimate a predicted amount of life lost for the insulation during one or more future time intervals based on the load forecast; and
estimate a remaining service life for the electrical apparatus based on the actual amount of life lost and the predicted amount of life lost.
